(19) United States
(12) Patent Application Publication
(10) Pub. No.: US 2025/0046685 A1
(43) Pub. Date: Feb. 6, 2025

(54) METHOD FOR FORMING A SEMICONDUCTOR DEVICE, AND A STRUCTURE FORMED BY THE METHOD

(71) Applicant: Siliconix Incorporated, San Jose, CA (US)

(72) Inventors: Barry LIN, Kaohsiung (TW); Tony CHIU, Kaohsiung (TW)

(73) Assignee: Siliconix Incorporated, San Jose, CA (US)

(21) Appl. No.: 18/230,221

(22) Filed: Aug. 4, 2023

(51) Int. Cl. H01L 23/495; H01L 23/00; H01L 23/31; H01L 23/544

(52) U.S. Cl. CPC H01L 23/49562; H01L 23/3107; H01L 23/49503; H01L 23/544; H01L 24/48; H01L 2223/54426; H01L 2224/48247; H01L 2924/13091

(57) ABSTRACT

A method for assembling a chip includes attaching a first side of each die of multiple dies to a respective at least one paddle of multiple paddles of a lead-frame strip, and attaching each of at least one paddle of multiple paddles of a clip-frame strip to a second side of the respective die of the multiple dies. As compared to a semiconductor-packaging method that places individual clips on the second sides of multiple dies one at a time, such a method can be less expensive, less complex, faster, have a higher yield, and/or can reduce the per-component cost of integrated circuits (ICs) and/or other components packaged according to this method.

### TECHNICAL FIELD

The disclosure relates to a method for manufacturing (also called “fabricating”) semiconductor integrated circuits, and more specifically to an improved method for packaging semiconductor integrated circuits.

### BACKGROUND

In the manufacture of known semiconductor integrated circuits, leads may be attached to both surfaces of a die. The attachment of one or more first leads to the die's conductive pads on a first (bottom) surface can be accomplished by placing the die on a paddle of a lead frame and forming a conductive connection to the one or more first leads, for example by soldering. This can be done with multiple leads per die or dies simultaneously, prior to the leads/die(s) being separated from the lead frame. Connection of one or second leads to the conductive pad on a second (top) surface of the die is then carried out individually (i.e., typically not at the same time as other second leads are placed and attached) and in a more complex manner as compared to the placing and attaching of the one or more first leads.

An improvement in this type of fabrication is needed to improve manufacturability as well as reduce the chance of defects.

### SUMMARY

In an embodiment, a method is provided that includes attaching a first side of each die of multiple dies to a respective at least one paddle of multiple paddles of a lead-frame strip, and attaching each of at least one paddle of multiple paddles of a clip-frame strip to a second side of a respective die of the multiple dies. As compared to a semiconductor-packaging method that places individual clips on the second sides of multiple dies one at a time, such a method can be less expensive, less complex, and/or faster, can have a higher yield, and/or can reduce the per-component cost of integrated circuits (ICs) and/or other components packaged according to this method.

In another embodiment, a semiconductor structure is provided that includes a lead frame having lead-frame paddles, a chip-frame having chip-frame paddles, and dies each having a respective first side coupled to a respective at least one lead-frame paddle of the lead-frame paddles and having a respective second side coupled to a respective at least one chip-frame paddle of the chip-frame paddles.

### BRIEF DESCRIPTION OF THE DRAWINGS

A more detailed understanding may be had from the following description, given by way of example in conjunction with the accompanying drawings, wherein like reference numerals in the figures indicate like elements, and wherein:

FIGS. 1A-1B are lead-side and non-lead-side views, respectively, of an NMOS power transistor, according to an embodiment;

FIG. 1C is a schematic symbol of the NMOS power transistor of FIGS. 1A-1B;

FIGS. 2A-2B are lead-side and non-lead-side views, respectively, of an NMOS power transistor represented by the schematic symbol of FIG. 1C, according to another embodiment;

FIG. 3A is plan view of a lead-frame (LF) strip and a chip-frame (CF) strip, according to an embodiment;

FIG. 3B is a plan view of a CF block of the CF strip of FIG. 3A disposed over, and in alignment with, an LF block of the LF strip of FIG. 3A, according to an embodiment;

FIG. 4 is a plan view of an LF block of an LF strip, according to an embodiment;

FIGS. 5A-5B are respective plan views of a bond-wireless version of the LF block of FIG. 4 with solder formed over the surfaces of the die paddles and lead bond pads, and of a bond-wire-reduced version of the LF block of FIG. 4 with solder formed over the surfaces of the die paddles and lead bond pads, according to an embodiment;

FIGS. 6A-6B are respective plan views of the bond-wireless version of the LF block of FIG. 5A with dies disposed over the pre-soldered die paddles, and of the bond-wire-reduced version of the LF strip of FIG. 5B with dies disposed over the pre-soldered die paddles, according to an embodiment;

FIGS. 7A-7B are respective plan views of the bond-wireless version of the LF block of FIG. 6A with solder formed over the exposed surfaces of the dies, and the bond-wire-reduced version of the LF block of FIG. 6B with solder formed over the exposed surfaces of the dies, according to an embodiment;

FIG. 8A is a plan view of a CF block aligned with, and disposed over, the bond-wireless version of the LF block of FIG. 7A, and paddles of the CF block each disposed over an exposed surface of a respective die, according to an embodiment;

FIG. 8B is a plan view of a CF block aligned with, and disposed over, the bond-wire-reduced version of the LF block of FIG. 7B, and paddles of the CF block each disposed over an exposed surface of a respective die, according to an embodiment;

FIG. 9 represents the bond-wireless version of CF block and the LF block of FIG. 8A covered with a die-encapsulation material, and also represents the bond-wire-reduced version of the CF block and the LF block of FIG. 8B covered with a die-encapsulation material, according to an embodiment;

FIG. 10 is a flow diagram of a method for forming a semiconductor integrated circuit (IC) such as the transistor of FIGS. 1A-1B and/or the transistor of FIGS. 2A-2B, according to an embodiment;

FIG. 11 is a schematic diagram of a system that includes one or more of the transistors of FIGS. 1A-1B and/or FIGS. 2A-2B, according to an embodiment.

### DETAILED DESCRIPTION

Certain terminology is used in the following description for convenience only and is not limiting. The words “inwardly” and “outwardly” refer to directions toward and away from the parts referenced in the drawings. The terms “top” and “bottom” refer to directions on the articles as shown in the drawings. A reference to a list of items that are cited as, for example, “at least one of a or b” (where a and b represent the items being listed) means any single one of the items a or b, or a combination of a and b. This would also apply to lists of three or more items in like manner so that individual ones of the items or combinations thereof are included. The terms “about” and “approximately” encompass+ or −10% of an indicated value unless otherwise noted. The terminology includes the words specifically noted above, derivatives thereof and words of similar import.

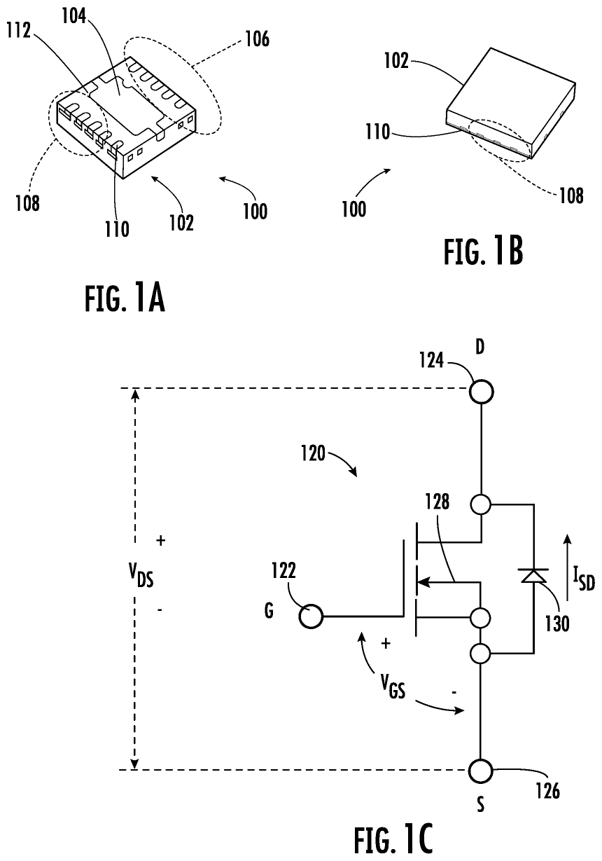

FIGS. 1A and 1B are isometric lead-side and non-lead-side views of a semiconductor integrated circuit (IC) 100, here an NMOS power transistor (also called a “semiconductor device”), having a Dual-Flat-No-Lead (DFN) package 102, according to an embodiment. The NMOS power transistor 100 is suitable for many applications such as being one of the switching transistors of a switching power supply (not shown in FIGS. 1A-1B). The package 102 includes an optional pad or plate 104, which may be a drain pad or which may be configured as a heat sink, one or more drain leads 106 (which may be coupled to the drain pad internal to the package), one or more source leads 108, one or more gate leads 110, and a housing 112. As described below in conjunction with FIG. 1C, the transistor 100 can be configured to have an inherent body diode (not shown in FIGS. 1A-1B) by virtue of the transistor's source (not shown in FIGS. 1A-1B) being coupled to the transistor's body region (not shown in FIGS. 1A-1B) inside of the housing 112. In an embodiment, the transistor 100 is a vertical enhancement-mode NMOS power transistor. Alternatively, the semiconductor integrated circuit 100 can be a microprocessor, microcontroller, analog-to-digital (A-to-D) converter, a Bluetooth® controller, disk-drive controller, wireless controller, a quad amplifier, or another type of IC.

FIG. 1C shows a schematic symbol 120 of the NMOS power transistor 100 of FIGS. 1A-1B in an embodiment where the transistor is an enhancement-mode transistor. Per the schematic symbol 120, the transistor 100 includes a gate (G) 122, an N-type drain (D) 124, an N-type source (S) 126, a P-type body 128, and an inherent PN-junction diode (typically called an “inherent body diode” or a “body diode”) 130. Referring to FIGS. 1A-1C, the gate 122 is coupled to the one or more gate leads 110, the source 126 is coupled to the one or more source leads 108, and the drain 124 is coupled to the one or more drain leads 106 of the package 102.

While the gate-to-source voltage V_{GS} is less than a threshold voltage V_{GS(th)}, the NMOS transistor 100 operates in its cut-off region during which the drain-to-source current IDS is relatively small (e.g., a few to tens of microamperes (A)), and is often approximated as =0 Amperes (A).

While V_{GS} is greater than V_{GS(th)} and the drain-to-source voltage VDS is less than V_{GS}−V_{GS(th)}, the NMOS transistor 100 operates in its linear or “triode” region, during which the value of IDS is proportional to V_{GS}−V_{GS(th)} for a given value of VDS.

And while V_{GS} is greater than V_{GS(th)} and VDS is greater than V_{GS}−V_{GS(th)}, the NMOS transistor 100 operates in its current-saturation region, during which the value of IDS is proportional to (V_{GS}− V_{GS(th)})² (many applications of the NMOS transistor call for configuring circuitry that includes the NMOS transistor such that the NMOS transistor operates in its current-saturation region).

If the drain voltage V_{D} goes below the source voltage Vs while the NMOS transistor 100 is operating in, or near, its cut-off region, then the inherent body diode 130 may conduct a source-to-drain current if the source-to-drain voltage V_{SD} is greater than the body diode's threshold, or “turn-on,” voltage Vₜh. For example, the body diode 130 may conduct a source-to-drain current I_{SD} for a relatively brief period during a discharge of a phase inductor of a switching power supply such as a buck converter.

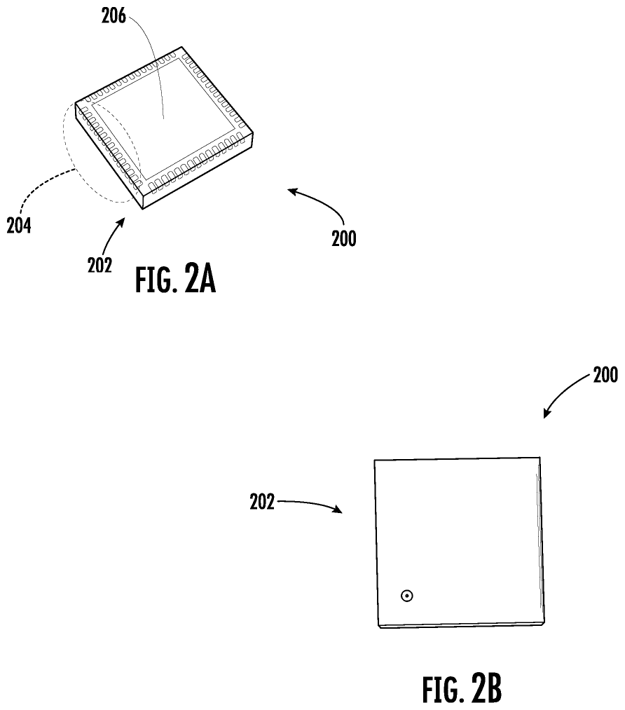

FIGS. 2A and 2B are isometric lead-side and non-lead-side views of a semiconductor integrated circuit 200 having a Quad-Flat-No-Lead (QFN) package with leads 204 and an optional heatsink/pad 206, according to an embodiment. For example, the semiconductor integrated circuit 202 can be a microprocessor, microcontroller, analog-to-digital (A-to-D) converter, a Bluetooth® controller, disk-drive controller, wireless controller or a quad amplifier, another type of IC, or can be a semiconductor device such as an NMOS transistor represented by the schematic symbol of FIG. 1C.

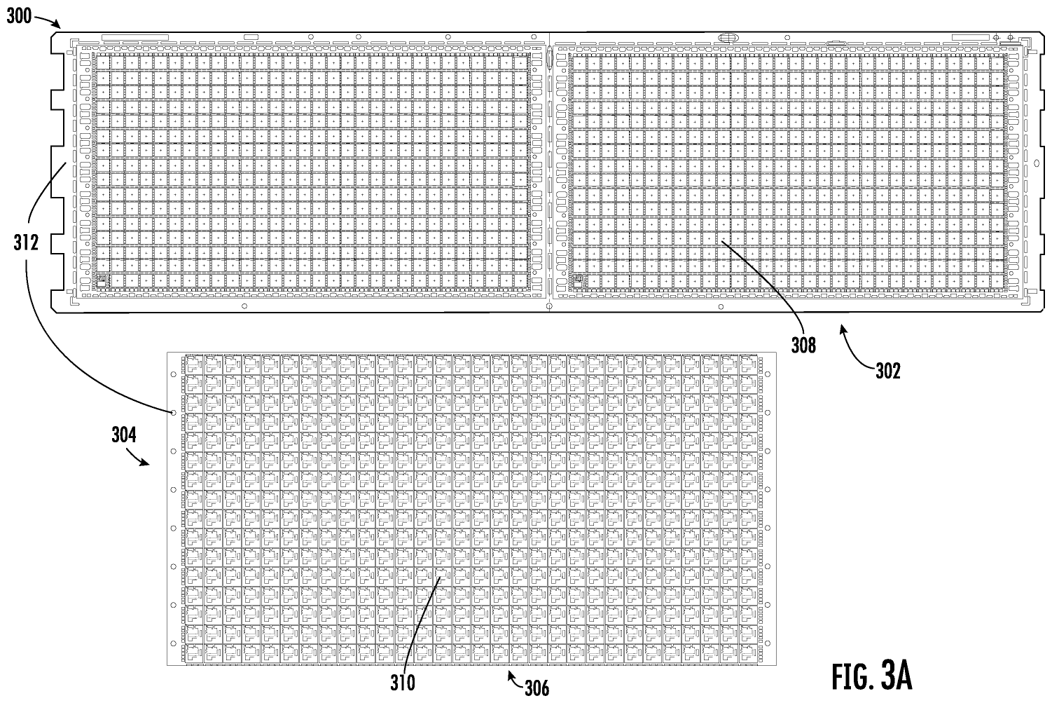

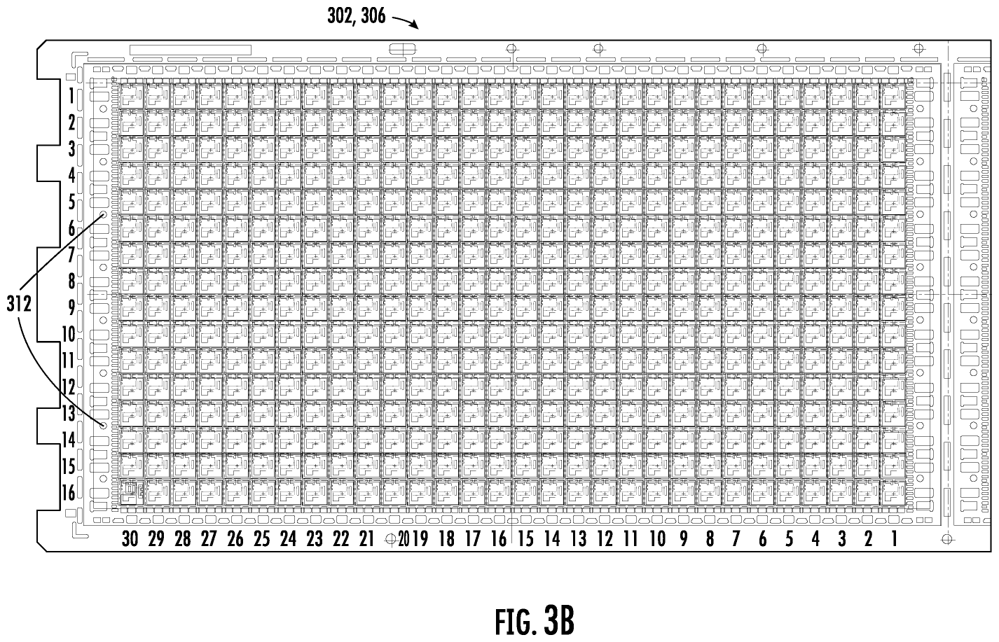

FIG. 3A is a plan view of a lead-frame strip 300 including one or more lead-frame blocks 302 (two shown) and a clip-frame strip 304 including one or more clip-frame blocks 306 (one shown), according to an embodiment.

FIG. 3B is a plan view of a clip-frame block 306 of the clip-frame strip 304 of FIG. 3A disposed over, and aligned with, an integrated-circuit-die-populated lead-frame block 302 of the lead-frame strip 300 of FIG. 3A, according to an embodiment.

The lead-frame strip 300 includes one or more lead-frame blocks 302 (two shown) serially connected together to form the lead-frame strip. Serially connecting multiple lead-frame blocks 302 to form the lead-frame strip 300 facilitates the below-described manufacturing method (also called a “manufacturing process”) because the lead-frame strip can be stored in a roll form and can be fed continuously and automatically into the first piece of manufacturing equipment of a manufacturing line instead of being fed into the first piece of equipment one lead-frame block at a time.

Each lead-frame block 302 includes subblocks 308 each having a respective one or more lead-frame paddles on which a respective one or more integrated-circuit dies are disposed, and one or more bonding pads on a side of each die facing a corresponding paddle are electrically coupled (typically by solder) to leads that are part of the lead-frame block.

The exposed second side of each integrated-circuit die also includes a respective one or more bonding pads for coupling to other leads as described below.

In a conventional manufacturing process, lead clips are respectively placed, one at a time, over the exposed sides of the integrated-circuit dies (which are disposed on the paddles in the sub-blocks 308 of the lead-frame blocks 302) and bonding pads on the second sides are electrically conductively connected (typically by soldering) to leads that are part of each of the clips.

To improve this manufacturing process, in an embodiment, the clip-frame strip 304 includes one or more clip-frame blocks 306 serially connected together (e.g., in a roll as described above for the lead-frame strip 300), and each clip-frame block includes a same number of clips 310 as the number of subblocks 308 in a lead-frame block 302.

In a manufacturing process that, according to an embodiment, improves upon the conventional manufacturing process, instead of placing the clips over, and conductively coupling the clips to, the exposed sides of the integrated-circuit dies of the lead-frame block 302 one at a time, a pick-and-place machine (not shown in FIGS. 3A-3B) picks up the entire clip-frame block 306, places the clip-frame block over, and aligns (using alignment features 312) the clip-frame block to, a corresponding lead-frame block 302, moves the clips into contact with the exposed sides of the integrated-circuit dies of the lead-frame block, and conductively connects (typically by soldering) bond pads of the dies to leads of the clips.

As compared to the conventional manufacturing process during which clips are placed, aligned, and soldered one at a time, an improved manufacturing process according to an embodiment, during which improved manufacturing process clips are placed, aligned, and soldered, one clip-frame block 306 at a time, can be less complex, can be faster (at least on a per-unit basis), and can yield a higher percentage of “passing” units. For example, the improved manufacturing process can reduce the number or severity of alignment errors (e.g., rotational alignment errors) that may occur between a clip and a die as compared to the conventional method. Furthermore, in about the time that the conventional method takes to place, align, and solder a single clip to a single die, the improved method can place, align, and solder multiple clips (e.g., up to the number of clips in one or more of the clip-frame blocks 306) to multiple dies.

Referring to FIGS. 3A-10 two versions of an improved semiconductor manufacturing method are described in conjunction with the forming of two versions of a semiconductor integrated circuit, according to an embodiment. In the first (bond-wireless) version, no bonding wires are used, and in the second (bond-wire reduced) version, few, one, or no bonding wire are/is used per die.

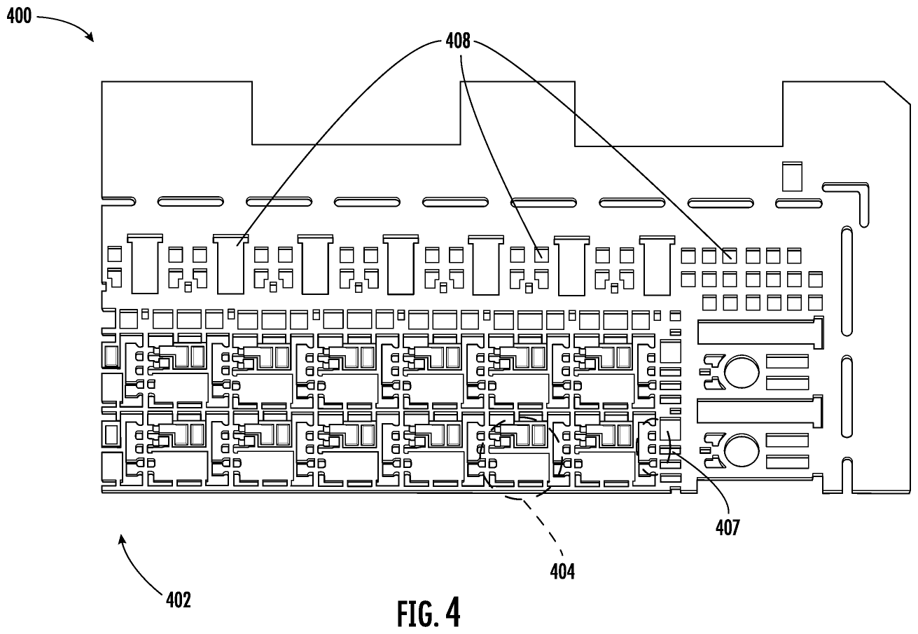

FIG. 4 is a plan view of a lead-frame (LF) block 400 of a lead-frame strip 402 having dual paddles 404, leads 406, and alignment holes and markings 408, according to an embodiment. Each set of the dual paddles 404 is configured to receive a pair (two) of dies that together will form a respective single packaged semiconductor integrated circuit. Although the lead-frame block 400 is shown as including twelve dual paddles 404 configured to accommodate, respectively, twenty four dies (not shown in FIG. 4), the lead-frame block can include any suitable number (e.g., sixteen, twenty four, thirty two, forty eight, sixty four, seventy two, ninety six, one hundred twenty, one hundred twenty eight, one hundred forty four, one hundred sixty eight, one hundred ninety two, two hundred sixteen, two hundred forty, or two hundred fifty six) of dual paddles configured to accommodate any suitable number (e.g., sixteen, twenty four, thirty two, forty eight, sixty four, seventy two, ninety six, one hundred twenty, one hundred twenty eight, one hundred forty four, one hundred sixty eight, one hundred ninety two, two hundred sixteen, two hundred forty, or two hundred fifty six) of dies. Furthermore, although described in conjunction with dual paddles 404, the bond-wireless and bond-wire-reduced of the described manufacturing method is compatible with single, triple, and other-capacity paddles.

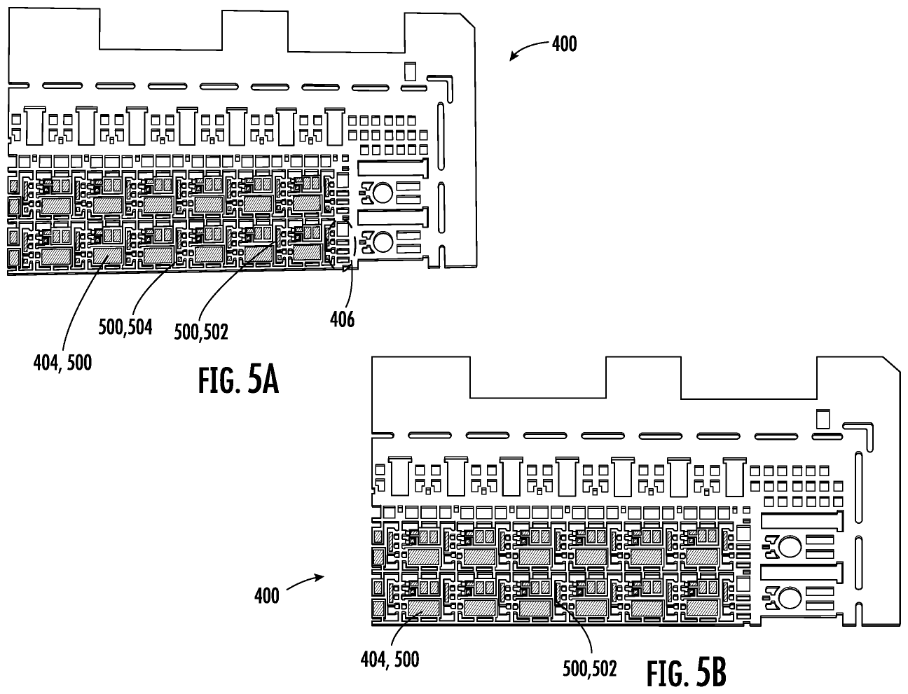

FIGS. 5A (bond-wireless version) and 5B (bond-wire-reduced version) are each a plan view of the lead-frame block 400 of FIG. 4 with solder 500 formed over surfaces of the die paddles 404 and over the lead bonding pads 502, according to an embodiment. Furthermore, in FIG. 5A, solder 500 is formed over surfaces of connector pads 504, according to an embodiment.

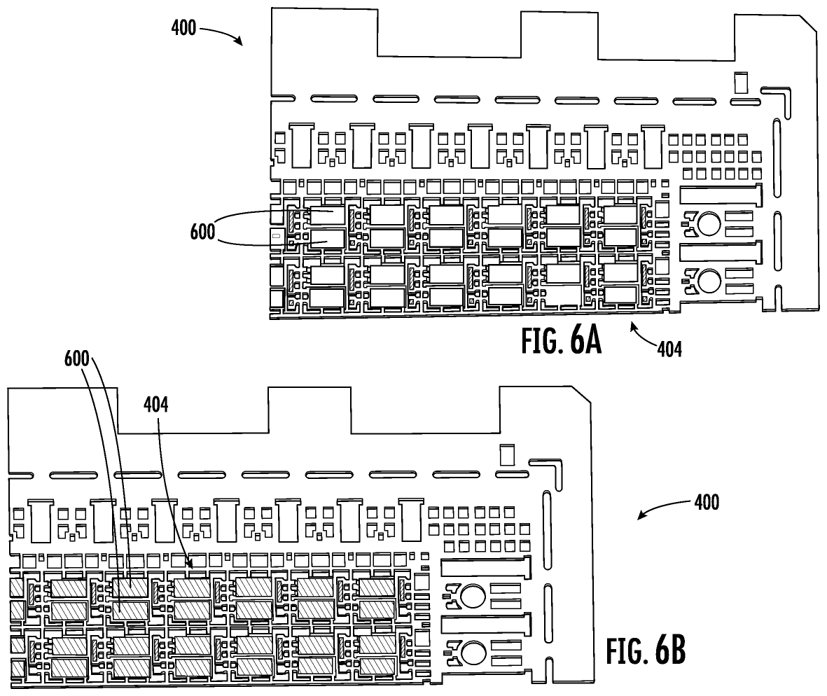

FIGS. 6A (bond-wireless version) and 6B (bond-wire-reduced version) are each a plan view of the lead-frame block 400 of FIGS. 5A and 5B, respectively, with dies 600 disposed over the pre-soldered die paddles 404, according to an embodiment.

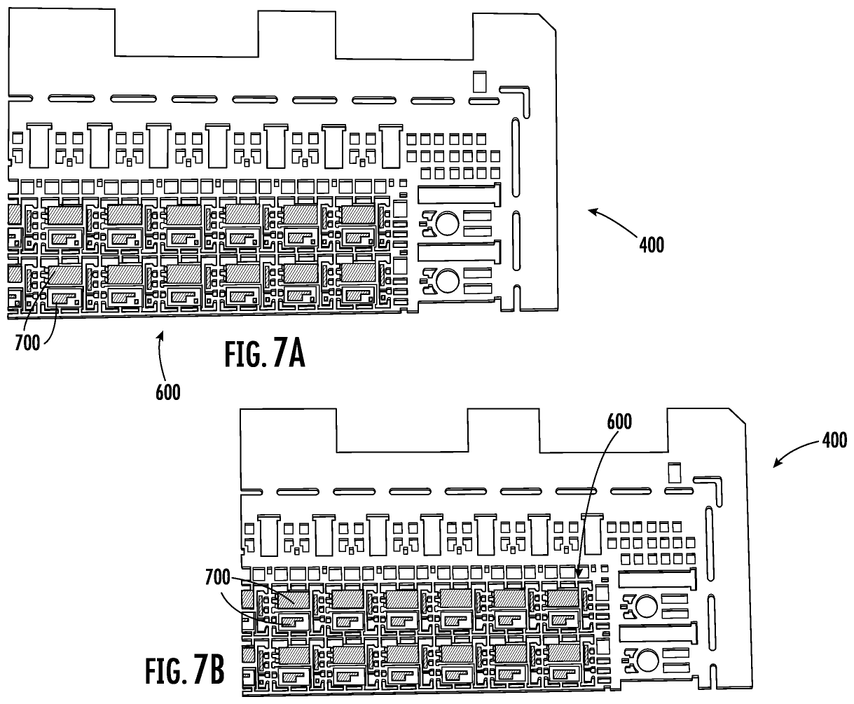

FIGS. 7A (bond-wireless version) and 7B bond-wire-reduced version) are each a plan view the lead-frame block 400 of FIGS. 6A and 6B, respectively, with solder formed over the exposed surfaces of the dies 600, according to an embodiment.

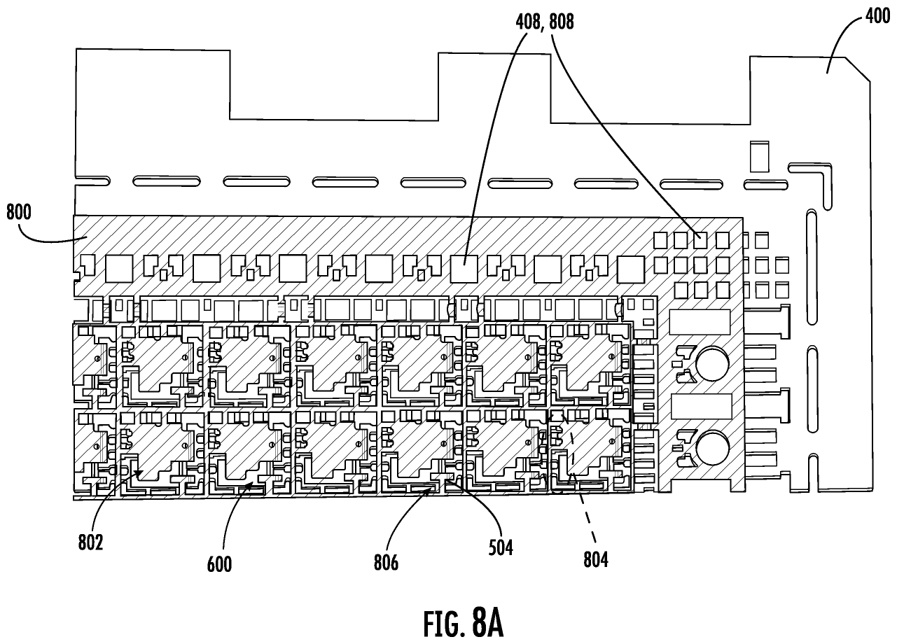

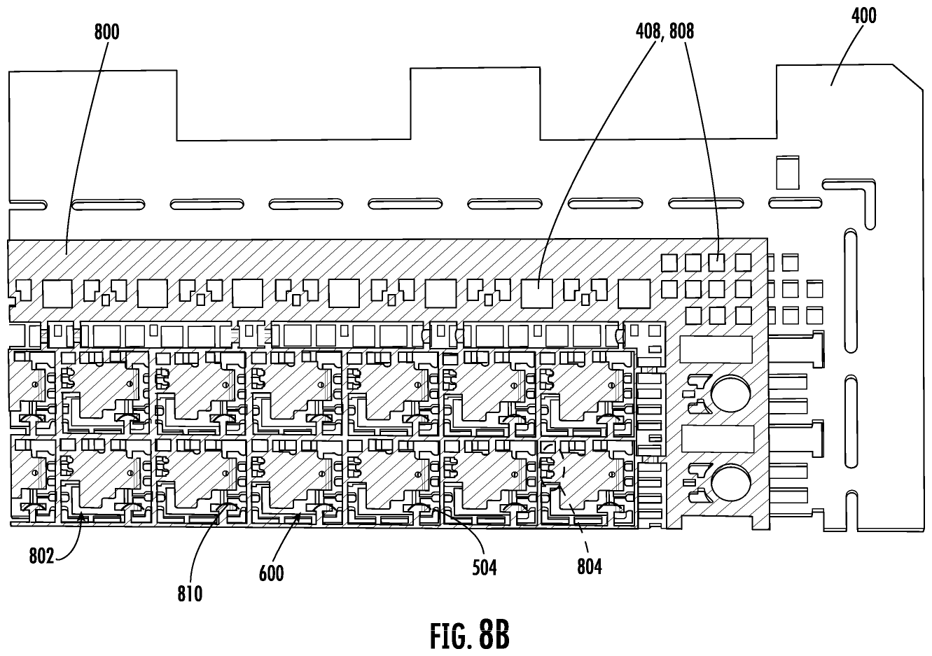

FIG. 8A (bond-wireless version) is a plan view of a clip-frame block 800 having die paddles 802, leads 804, clip connectors 806, and alignment holes and markings 808, disposed over the lead-frame block 400 of FIG. 7A such that the alignment holes and markings are aligned with the corresponding alignment holes and markings 407 (see FIG. 4) of the lead-frame block and such that the clip-frame-strip paddles 802 each are disposed over an exposed surface of a respective die 600 and each include conductive pads (not shown in FIG. 8A) conductively coupled (such as by solder) to corresponding conductive pads on the die surface, according to an embodiment. And the clip connectors 806 conductively couple (such as by solder) the conductive lead pads 504 of the lead-frame block 400 to respective bonds on the exposed sides of the dies 600.

FIG. 8B (bond-wire-reduced version) is a plan view of a clip-frame block 800 having die paddles 802, leads 804, bond wires 810 (one bond wire per die), and alignment holes and markings 808, disposed over the lead-frame block 400 of FIG. 7B such that the alignment holes and markings are aligned with the corresponding alignment holes and markings 407 (see FIG. 4) of the lead-frame block and such that the clip-frame-strip paddles 802 each are disposed over an exposed surface of a respective die 600 and each include conductive pads (not shown in FIG. 8B?) conductively coupled (such as by solder) to corresponding conductive pads on the die surface, according to an embodiment. And the bond wires 810 conductively couple (such as by solder) the conductive lead pads 504 of the lead-frame block 400 to respective bonds on the exposed sides of the dies 600. That is, the bond wires 810 effectively replace the clip connectors 806 of FIG. 8A.

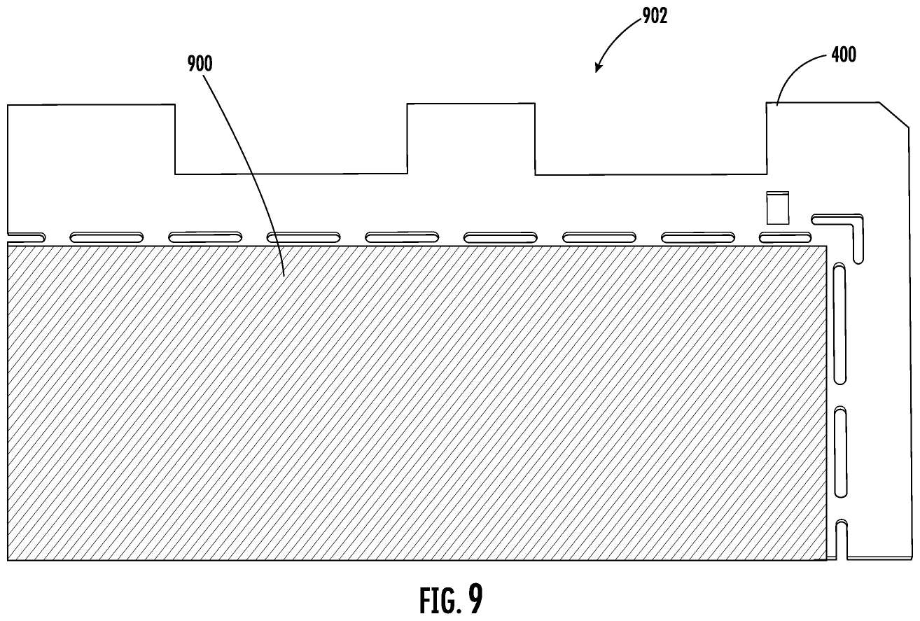

FIG. 9 is a plan view of the clip-frame block 800 (not visible in FIG. 9) and the lead-frame block 400 of FIGS. 8A (bond-wireless version) or 8B (bond-wire-reduced version) with the dies 600, leads 406 and 804, pads 504, clips 806 (FIG. 8A), and bond wires 810 (none visible in FIG. 9) covered in a housing material 900 (e.g., an epoxy resin), according to an embodiment;

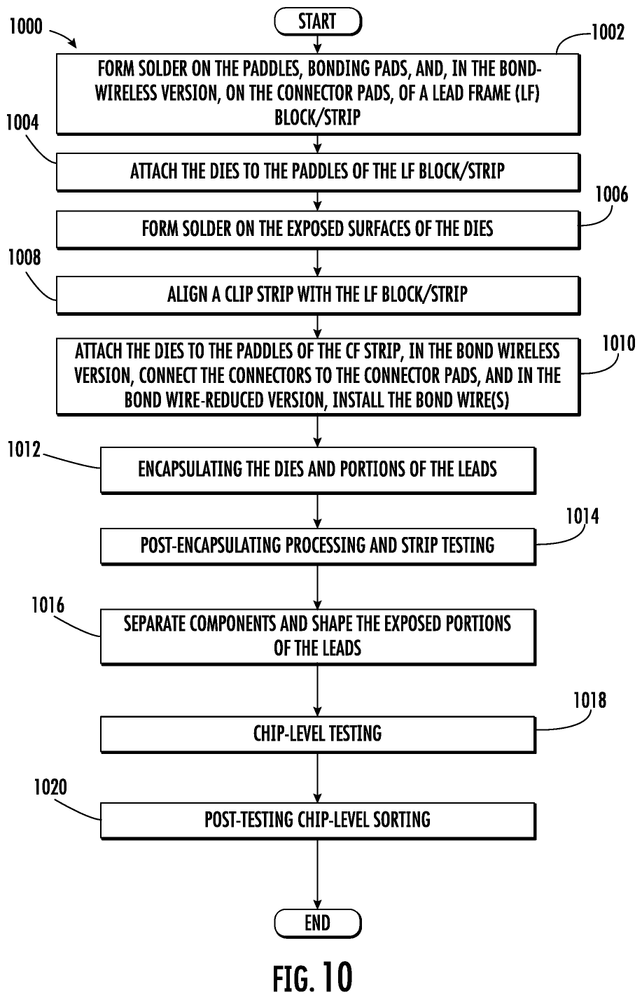

FIG. 10 is a flow diagram 1000 of bond-wireless and bond-wired-reduced versions of a method (sometimes called a “semiconductor process” or a “semiconductor manufacturing process”) for forming a semiconductor device such as the semiconductor integrated circuit (transistor) 100 of FIGS. 1A-1B or the semiconductor integrated circuit (transistor) 200 of FIGS. 2A-2B, according to an embodiment.

Referring to FIGS. 4-10, bond-wireless and bond-wire-reduced versions of a semiconductor processes for manufacturing a semiconductor device or integrated circuit, such as the semiconductor integrated circuit (transistor) 100 of FIGS. 1A-1B or semiconductor integrated circuit (transistor) 200 of FIGS. 2A-2B, are described according to an embodiment. The procedures and resulting structures of the described versions of the method and intermediate structures are the same or similar unless otherwise noted.

Referring to FIGS. 4 and 10, the unpopulated lead-frame block 400 is introduced to the processing line. The lead-frame block 400 may be part of a lead-frame strip 300 including multiple lead-frame blocks, and the lead-frame block can be separated (e.g., by manufacturing equipment) from the lead-frame strip at any suitable point in the process, for example, before, or shortly after, introducing the lead-frame block to the processing line.

Referring to FIGS. 5A-5B and 10, at 1002, solder 500 is formed on the die paddles 404, the lead bonding pads 502 and, in the bond-wireless version of the method (FIG. 5A), on the connector pads 504 of the lead-frame block 400. For example, the solder 500 may be printed on conductive pads (not shown in FIGS. 5A and 5B) that are disposed on the paddles 404 and that are respectively coupled to one or more of the leads 406. And the solder 500 also can act as an adhesive to secure dies (see FIG. 6) to the paddles 404; alternatively, an adhesive separate from the solder can be formed, for example, by printing, on portions of the paddles other than the conductive pads. In an embodiment, solder printing is a suitable solder-forming technique because it can offer precise control of the volume of solder being deposited onto the paddles 404, the lead bonding pads 502, the connector pads 504, and any other component(s) of the lead-frame block 400.

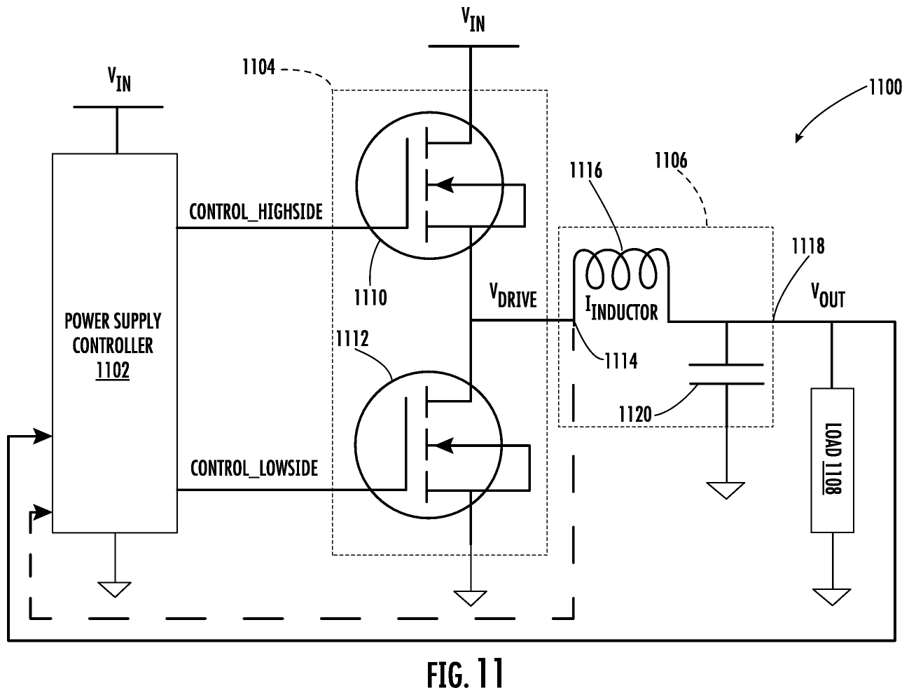

Referring to FIGS. 6A-6B, at 1004 the dies 600 are attached to the dual die paddles 404 of the lead-frame strip 400 (two dies per paddle in the described embodiment). The dies 600 are attached to the paddles 404 such that solder 500 (FIG. 5) conductively couples conductive pads (not shown in FIGS. 6A-6B) on the bottom surfaces of the dies to corresponding conductive pads (not shown in FIGS. 6A-6B) on the die-facing surfaces of the paddles 404, where these paddle conductive pads are conductively coupled to respective sets of the leads 406. For example, the item 1004 can include a solder reflow. Consequently, after completion of the item 1004, circuitry on each of the dies 600 is coupled to a respective set of the leads 406 via the conductive pads of the paddles 404, solder, and the conductive pads of the dies 600. And, as stated above in conjunction with FIGS. 5A-5B and 11, the dies 600 can be secured to the paddles 404 by the solder 500 (e.g., adhesive solder) or by a separate adhesive.

Referring to FIGS. 7A-7B and 10, at 1006, solder is formed on the exposed surfaces (upper surfaces in FIGS. 7A-7B) of the dies 600. For example, the solder may be printed on conductive pads (not shown in FIGS. 7A-7B) that are disposed on the exposed surfaces of the dies 600 and that are respectively coupled to respective circuitry on the dies. And the solder also can act as an adhesive to secure the dies 600 to paddles 802 of the clip-frame strip 800 as described below in conjunction with FIGS. 8A-8B; alternatively, an adhesive separate from the solder can be formed, for example by printing, on portions of the dies' upper surfaces other than the conductive pads. In an embodiment, solder printing is a suitable solder-forming technique because it can offer precise control of the volume of solder being deposited onto the dies 600.

Referring to FIGS. 8A and 10, at 1008, during the bond-wireless version of the method, the clip-frame block 800 is aligned with the lead-frame block 400. For example, the blocks 400 and 800 are aligned by using one or more alignment tools (not shown in FIG. 8A) to align the alignment holes or marks 408 with the corresponding alignment holes or marks 808. As a result of such an alignment of the clip-frame block 800 with the lead-frame block 400, each of the paddles 802 of the clip-frame block is aligned with a corresponding one of the paddles 404 (see FIG. 4) of the lead-frame strip 400 and, therefore, is aligned with a corresponding one of the dies 600. As a result of the alignment of the lead-frame block 400 with the clip-frame block 800, each of the dies 600 is effectively “sandwiched” between a corresponding pair of the paddles 404 and 802. Furthermore, the clip connectors 806 of the chip-frame block 800 are aligned with the connector pads 504 and corresponding bond pads on the exposed (upper) surfaces of the dies 600.

Still referring to FIGS. 8A and 10 and still during the bond-wireless version of the manufacturing method, at 1010 the clip-frame block 800 is moved toward the lead-frame block 400 while alignment is obtained to attach the paddles 802 of the clip-frame block to the dies 600 (to the exposed or upper die surfaces). The paddles 802 are attached to the dies 600 such that the solder (FIG. 7A) conductively couples conductive pads (not shown in FIG. 8A) on the exposed surfaces (the top surfaces in FIG. 7A) of the dies to corresponding conductive pads (not shown in FIG. 8A) on the die-facing surfaces of the paddles 802, where these paddle conductive pads are conductively coupled to respective sets of the leads 804. For example, the item 1010 can include a solder reflow. Consequently, after completion of the item 1010, circuitry on each of the dies 600 is coupled to a respective set of the leads 804 via the conductive pads of the paddles 802, solder, the conductive pads on the top surfaces (the surfaces facing the paddles 802) of the dies 600, the connector 806, and the pad 504. And, as stated above in conjunction with FIGS. 7A and 10, the paddles 802 can be secured to the dies 600 by the solder (e.g., adhesive solder) or by a separate adhesive.

Referring to FIGS. 8B and 10, at 1008, during the bond-wire-reducing version of the method, the clip-frame block 800 is aligned with the lead-frame block 400. For example, the blocks 400 and 800 are aligned by using one or more alignment tools (not shown in FIG. 8B) to align the alignment holes or marks 408 with the corresponding alignment holes or marks 808. As a result of such an alignment of the clip-frame block 800 with the lead-frame block 400, each of the paddles 802 of the clip-frame block is aligned with a corresponding one of the paddles 404 (see FIG. 4) of the lead-frame strip 400 and, therefore, is aligned with a corresponding one of the dies 600. As a result of the alignment of the lead-frame block 400 with the clip-frame block 800, each of the dies 600 is effectively “sandwiched” between a corresponding pair of the paddles 404 and 802.

Still referring to FIGS. 8B and 10 and still during the bond-wire-reducing version of the manufacturing method, at 1010 the clip-frame block 800 is moved toward the lead-frame block 400 while alignment is obtained to attach the paddles 802 of the clip-frame block to the dies 700 (to the exposed or upper die surfaces). The paddles 802 are attached to the dies 600 such that the solder (FIG. 7B) electrically couples conductive pads (not shown in FIG. 8B) on the exposed surfaces (the top surfaces in FIG. 7B) of the dies to corresponding conductive pads (not shown in FIG. 8B) on the die-facing surfaces of the paddles 802, where these paddle conductive pads are electrically coupled to respective sets of the leads 804. For example, the item 1010 can include a solder reflow. And instead of the connectors, the bond wires 810 are installed to conductively connect the connector pads 504 and corresponding bond pads on the exposed (upper) surfaces of the dies 600. Consequently, after completion of the item 1010, circuitry on each of the dies 600 is coupled to a respective set of the leads 804 via the conductive pads of the paddles 802, solder, the conductive pads on the top surfaces (the surfaces facing the paddles 802) of the dies 600, the bond wire 810, and the pad 504. And, as stated above in conjunction with FIGS. 7B and 10, the paddles 802 can be secured to the dies 600 by the solder (e.g., adhesive solder) or by a separate adhesive.

Referring to FIGS. 9 and 10, at 1012 the dies 600 of FIG. 8A or 8B (dies not visible in FIG. 9) are covered, or encapsulated, with a suitable material 900, such as epoxy resin, to form housings such as housings 112 of FIGS. 1A-1B or housing 208 of FIGS. 2A-2B. For example, an epoxy or other plastic may be molded (e.g., injection or another type of molding) around the dies 600 to form the housings, or deposited and etched to form the housings. Or the housings may be formed by a ceramic and/or may be hermetically sealed. And, in another example, the encapsulated dies 700 may each be formed to include a respective heat sink or other conductive plate such as the plate 104 of FIGS. 1A-1B or the plate 206 of FIGS. 2A-2B.

Still referring to FIGS. 9 and 10, at 1014, the resulting structure 902 (for example, after individual housings are formed) is processed post-encapsulating. For example, the structure 902 (after forming individual housings) is de-junked or otherwise cleaned, the exposed portions of the leads 406 and 804 are plated, for example, with tin (Sn), and the housings are laser marked, for example with the part number and provider.

Next, at 1016, the housed semiconductor integrated circuits, components, devices, or chips are separated from the lead-frame and chip-frame blocks 400 and 800, and, referring to FIGS. 1A-2B, the exposed portions of the leads 406 and 804 remaining after component separation are shaped to form the external leads 106, 108, 110, and 204.

Then, at 1018, the separated semiconductor integrated circuits, components, devices, or chips, are tested. For example, the components may be subject to electrical-signal tests such as a JTAG boundary scan or electrical- and heat-stressing tests.

Next, at 1020, the semiconductor integrated circuits, components, devices, or chips are sorted based on the results of the tests at item 1018.

Referring again to FIGS. 4-10, the bond-wireless and the bond-wire-reduced versions of the semiconductor process described in conjunction with the flow diagram 1000 can yield bond-wireless and/or bond-wire-reduced semiconductor integrated circuits, components, devices, or chips that are, on a per-chip basis, up to about 40% less expensive to manufacture than counterpart chips manufactured by other processes, and can increase the yield of acceptable units by up to about 1.5%.

FIG. 11 is a schematic diagram of a system 1100, which incorporates one or more of the NMOS transistors 100 or 200 of FIGS. 1A-2B, according to an embodiment. For purposes of explanation, the system 1100 is described as including two NMOS transistors 100, although it is understood that the system 1100 would be configured and would function similarly if one or both of the transistors were replaced with an NMOS transistor 200.

In an embodiment, the system 1100 is a single-phase buck-converter power supply, which includes a power-supply controller 1102, a switching circuit 1104, and a filter circuit 1106, and which is configured to provide a regulated output voltage Voₜ to a load 1108.

The controller 1102 can be a conventional power-supply controller, and is configured to receive, as a feedback signal, Vₒᵤₜ (or a derivative thereof), and also may be configured to receive, as another feedback signal, V_{drive} (or a derivative thereof), depending on the control mode in which the power supply 1100 is configured to operate. For example, if the controller 1102 employs current-mode control, then the controller may form a current-control loop that receives, as in input, the voltage V_{drive}. The controller 1102 is also coupled between Vin, which powers the controller, and circuit ground.

The switching circuit 1104 includes a high-side NMOS transistor 1110 and a low-side NMOS transistor 1112, which are both the same as, or similar to, the NMOS transistor 100 of FIGS. 1A-1B. The high-side transistor 1110 has its drain coupled to an input voltage Vin, its gate coupled to receive a control signal Control_Highside from the controller 1102, and its source coupled to an input node 1114 of the filter circuit 1106. The low-side transistor 1112 has its drain coupled to the input node 1114 of the filter circuit 1106, its gate coupled to receive a control signal Control_Lowside from the controller 1102, and its source coupled to circuit ground.

The filter circuit 1106 includes an inductor 1116 coupled between the input and output nodes 1114 and 1118 of the filter circuit 1106, and includes a capacitor 1120 coupled between the output node 1118 of the filter circuit and circuit ground.

The load 1108 can be any suitable load, such as a microprocessor, microcontroller, or other integrated circuit.

In operation, the power-supply controller 1102 generates Control_Highside having a level that turns the transistor 1110 “on” and generates Control_Lowside having a level that turns the transistor 1112 “off.”

A linearly increasing current l_{inductor} flows from Vin, through the drain-source junction of the “on” transistor 1110, and through the inductor 1116, to the capacitor 1120 and load 1108. Respective components of this linearly increasing current I_{inductor} power the load 1108 and charge the capacitor 1120.

After a period of time, the power-supply controller 1102 generates Control_Highside having a level that turns the transistor 1110 “off” and generates Control_Lowside having a level that turns the transistor 1112 “on.”

After this switching transition, a linearly decreasing current l_{inductor} flows from circuit ground, through the source-drain junction of the “on” transistor 1112, and through the inductor 1116, to the capacitor 1120 and load 1108. Respective components of this linearly decreasing current l_{inductor} power the load 1108 and charge the capacitor 1120 (although when l_{inductor} reduces to a threshold level the capacitor may begin to discharge such that the voltage, Vₒᵤₜ, across the capacitor is regulated). Depending on the timing of the turning “off” of the transistor 1110 relative to the turning “on” of the transistor 1112, the inherent body diode (see FIG. 1B) of the transistor 1112 may be forward biased and conduct I_{inductor} for a period of time before the transistor 1112 is fully “on.”

The power-supply controller 1102 thereafter repeats this switching cycle, adjusting the duty cycle of the transistor 1110 in a manner that regulates Vₒᵤₜ to a value, such as 1.1 Volts (V), for which the controller 1102 and power supply 1100 are configured.

Further details regarding the structure and operation of the power supply 1100 and similar power supplies are known.

Referring to FIGS. 1A-1B, 2A-14, alternate embodiments are contemplated. For example, although the process for packaging an NMOS transistor is described, other semiconductor integrated circuits (ICs), components, devices, and/or chips, such as a PMOS transistor, a bipolar transistor, a BiCMOS transistor, and A/D converter, a wireless or Bluetooth® integrated circuit, a disk-drive controller, a motor controller, a microcontroller, and/or a microprocessor, can be packaged according to the bond-wireless or bond-wire-reduced versions of the above-described semiconductor-packaging process. Furthermore, the system 1100 can be a power supply other than a single-phase buck converter, for example, a multi-phase buck converter with or without coupled inductors, a boost converter, a buck-boost converter, and/or a flyback converter, can be a current regulator instead of, and/or in addition to, a voltage regulator, and/or can be a system (e.g., a computer system) other than a power supply.

Although the features and elements of the disclosed subject matter are described in embodiments in particular combinations, each feature or element may be used alone without the other features and elements of the embodiments or in various combinations with or without other features and elements of the disclosed subject matter.

While features and elements are described above in particular combinations, one of ordinary skill in the art will appreciate that each feature or element can be used alone or in any combination with the other features and elements.

What is claimed:

1. A method, comprising:
attaching a first side of each die of multiple dies to a respective at least one paddle of multiple paddles of a lead-frame strip; and
attaching each of at least one paddle of multiple paddles of a clip-frame strip to a second side of a respective said die of the multiple dies.

2. The method of claim 1, wherein the attaching the first side includes attaching the first side of each said die of the multiple dies to the respective at least one paddle of the multiple paddles of the lead-frame strip one at a time.

3. The method of claim 1, wherein the attaching each said at least one paddle of the multiple paddles includes attaching each of said at least one paddle of the multiple paddles of the clip-frame strip to the second side of the respective die of the multiple dies while the multiple paddles are connected to the clip-frame strip.

4. The method of claim 1, wherein:
the attaching the first side includes soldering the first side of each said die of the multiple dies to the respective at least one paddle of the multiple paddles of the lead-frame strip; and
the attaching of each said at least one paddle of the multiple paddles of the clip-frame strip includes soldering each said at least one paddle of the multiple paddles of the clip-frame strip to the second side of the respective die of the multiple dies.

5. The method of claim 1, further comprising:
forming solder on each said at least one paddle of the multiple paddles of the lead-frame strip before attaching the first side of each said die of the multiple dies to the respective at least one paddle of the multiple paddles of the lead-frame strip; and
forming solder on each said at least one paddle of the multiple paddles of the clip-frame strip before attaching each said at least one paddle of the multiple paddles of the clip-frame strip to the second side of the respective die of the multiple dies.

6. The method of claim 1, further comprising aligning the clip-frame strip with the lead-frame strip before attaching each said at least one paddle of the multiple paddles of the clip-frame strip to the respective second side of each said die of the multiple dies.

7. The method of claim 1, further comprising aligning alignment marks of the clip-frame strip with corresponding alignment marks of the lead-frame strip before attaching the multiple paddles of the clip-frame strip to the second sides of the multiple dies.

8. The method of claim 1, further comprising encapsulating each said die of the multiple dies to form chips.

9. The method of claim 8, further comprising testing the chips before separating the chips from the lead-frame and the clip-frame strips.

10. The method of claim 8, further comprising de-junking the chips, the lead-frame strip, and the clip-frame strip before separating the chips from the lead-frame and the clip-frame strips.

11. The method of claim 8, further comprising plating exposed leads of the chips before separating the chips from the lead-frame and the clip-frame strips.

12. The method of claim 8, further comprising marking housings formed by the encapsulating of the chips before separating the chips from the lead-frame and clip-frame strips.

13. The method of claim 8, further comprising separating the chips from the lead-frame and the clip-frame strips.

14. The method of claim 13, further comprising shaping exposed leads of the chips after separating the chips from the lead-frame and the clip-frame strips.

15. The method of claim 1, wherein:
the lead frame includes at least one lead-frame block;
a chip-frame including at least one chip-frame block; and
the attaching each said at least one paddle of the multiple paddles of the clip-frame strip to the second side of the respective die of the multiple dies includes placing the at least one chip-frame block over the at least one lead-frame block.

16. The method of claim 1, wherein:
the lead frame includes at least one lead-frame block;
a chip-frame including at least one chip-frame block; and
the attaching each said at least one paddle of the multiple paddles of the clip-frame strip to the second side of the respective die of the multiple dies includes placing the at least one chip-frame block over the at least one lead-frame block and aligning the at least one chip-frame block with the at least one lead-frame block.

17. A semiconductor structure, comprising:
a lead frame having lead-frame paddles;
a chip-frame having chip-frame paddles;
dies each having a respective first side coupled to a respective lead-frame paddle of the lead-frame paddles and having a respective second side coupled to a respective chip-frame paddle of the chip-frame paddles.

18. The semiconductor structure of claim 17, further comprising:
wherein each die of the multiple dies has a respective bond pad;
wherein the lead frame or the chip-frame has multiple leads each corresponding to the respective die of the multiple dies; and
bond wires each coupled between the bond pad of the respective die of the multiple dies and the corresponding lead of the multiple leads.

19. The semiconductor structure of claim 17, wherein:
each said die of the multiple dies has a respective bond pad;
the lead frame or the chip-frame has multiple leads each corresponding to the respective die of the multiple dies; and
the other of the lead frame or the chip-frame has multiple extensions each coupled between the bond pad of the respective die of the multiple dies and the corresponding lead of the multiple leads.

20. The semiconductor structure of claim 17, wherein:
each said die of the multiple dies has a respective bond pad;
the lead frame has multiple leads each corresponding to the respective die of the multiple dies; and
a clip-frame has multiple clip extensions each coupled between the bond pad of the respective die of the multiple dies and the corresponding lead of the multiple leads.
